(19) United States
(12) Patent Application Publication
(10) Pub. No.: US 2017/0121173 A1
(43) Pub. Date: May 4, 2017

(54) PACKAGING FOR MEMS TRANSDUCERS

(71) Applicant: Cirrus Logic International Semiconductor Ltd., Edinburgh (GB)

(72) Inventor: Tsjerk HOEKSTRA, Balerno (GB)

(73) Assignee: Cirrus Logic International Semiconductor Ltd., Edinburgh (GB)

(21) Appl. No.: 15/317,004

(22) PCT Filed: Jun. 9, 2015
(86) PCT No.: PCT/GB2015/051687

§ 371 Date: Dec. 7, 2016

(30) Foreign Application Priority Data
Jun. 10, 2014 (GB) 1410263.6

(51) Int. Cl. B81B 7/00; H04R 1/04

(52) U.S. Cl. CPC B81B 7/0077; B81B 7/0064; B81B 7/0038; H04R 1/04; B81B 2207/012; B81B 2201/0257; H04R 2201/003

(57) ABSTRACT

This application describes methods and apparatus relating to packaging of MEMS transducers and to MEMS transducer packages. The application describes a MEMS transducer package (300) having a first integrated circuit die (200) which has an integrated MEMS transducer (202) and integrated electronic circuitry (203) for operation of the MEMS transducer. The package is arranged such that the footprint of the MEMS transducer package is substantially the same size as the footprint of the integrated circuit die. At least part of the first integrated circuit die (200) may form a sidewall of the package. The package may be formed by a first package cover (302) which overlies the MEMS transducer and a second package cover (301) on the other side of the first integrated circuit die.

This application relates to methods and apparatus for packaging of a MEMS transducer and to packages for or comprising a MEMS transducer, and, in particular, for providing a package for a MEMS transducer, such as a MEMS microphone, formed on an integrated circuit die.

### BACKGROUND

Consumer electronics devices are continually getting smaller and, with advances in technology, are gaining ever-increasing performance and functionality. This is clearly evident in the technology used in consumer electronic products and especially, but not exclusively, portable products such as mobile phones, audio players, video players, PDAs, mobile computing platforms such as laptop computers or tablets and/or games devices. Requirements of the mobile phone industry for example, are driving the components to become smaller with higher functionality and reduced cost. It is therefore desirable to integrate functions of electronic circuits together and combine them with transducer devices such as microphones and speakers.

Micro-electromechanical-system (MEMS) transducers, such as MEMS microphones are finding application in many of these devices. There is therefore also a continual drive to reduce the size and cost of the MEMS devices.

Microphone devices formed using MEMS fabrication processes typically comprise one or more membranes with electrodes for read-out/drive deposited on the membranes and/or a substrate. In the case of MEMS pressure sensors and microphones, the read out is usually accomplished by measuring the capacitance between the electrodes. In the case of output transducers, the membrane is moved by electrostatic forces generated by varying a potential difference applied across the electrodes.

To provide protection the MEMS transducer will be contained within a package. The package effectively encloses the MEMS transducer and can provide environmental protection and may also provide shielding for electromagnetic interference (EMI) or the like. For microphones and the like the package will typically have a sound port to allow transmission of sound waves to/from the transducer within the package and the transducer may be configured so that the flexible membrane is located between first and second volumes, i.e. spaces/cavities that may be filled with air (or some other gas suitable for transmission of acoustic waves), and which are sized sufficiently so that the transducer provides the desired acoustic response. The sound port acoustically couples to a first volume on one side of the transducer membrane, which may sometimes be referred to as a front volume. The second volume, sometimes referred to as a back volume, on the other side of the one of more membranes is generally required to allow the membrane to move freely in response to incident sound or pressure waves, and this back volume may be substantially sealed (although it will be appreciated by one skilled in the art that for MEMS microphones and the like the first and second volumes may be connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like.

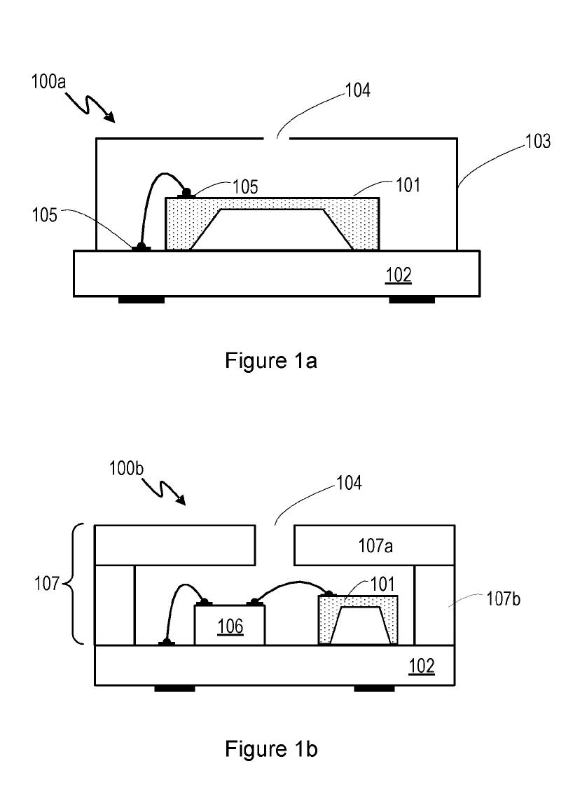

FIG. 1a illustrates one conventional MEMS microphone package 100a. A MEMS transducer 101 attached to a first surface of a package substrate 102. The MEMS transducer may typically be formed on a semiconductor die by known MEMS fabrication techniques. The package substrate 102 may be silicon or PCB or any other suitable material. A cover 103 is located over the transducer 101 attached to the first surface of the package substrate 102. The cover 103 may be a metallic lid. An aperture 104 in the cover 103 provides the sound port and allows acoustic signals to enter the package. In this example the transducer 101 is wire bonded to the substrate 102 via terminal pads on 105 on the package substrate 102 and transducer 101.

FIG. 1b illustrates another known MEMS transducer package 100b. Again a transducer 101, which may be a MEMS microphone, is attached to the first surface of a package substrate 102. In this example the package also contains an integrated circuit 106. The integrated circuit 106 may be provided for operation of the transducer and may for example be a low-noise amplifier for amplifying the signal from a MEMS microphone. The integrated circuit 106 is electrically connected to electrodes of the transducer 101 and is also attached to the first surface of the package substrate 102.

The integrated circuit 106 is bonded to the transducer 101 via wire-bonding. A cover 107 is located on the package substrate so as to enclose the transducer 101 and the integrated circuit 106. In this package the cover 107 comprises an upper part or lid portion 107a and two side walls 107b which are all formed of PCB. The cover 107 has a sound port 104 in the upper part 107a which allows acoustic signals to enter the package.

Embodiments of the present invention relate to improved packaging methods for MEMS transducers and to improved packages for MEMS transducers

According to the present invention there is provided

a MEMS transducer package comprising a first integrated circuit die,
the first integrated circuit die comprising:
   an integrated MEMS transducer; and
   integrated electronic circuitry for operation of the MEMS transducer;

wherein
the footprint of the MEMS transducer package is substantially the same size as the footprint of the integrated circuit die.

In some embodiments the MEMS transducer package may further comprise a first package cover which overlies the MEMS transducer, wherein at least part of the outer surface of the MEMS transducer package is formed by the first package cover. A barrier may also be provided around the MEMS transducer between the first package cover and the first integrated circuit die.

A first volume may be defined by the first integrated circuit die, the barrier and the first package cover. The barrier may comprise a layer of an adhesive material.

In some embodiments the first package cover comprises an aperture. A sealing ring may be provided on the outer surface of the first package cover surrounding the aperture. In some embodiments the MEMS transducer package may further comprise a water-resistant membrane disposed across said aperture.

In some embodiments the MEMS transducer package comprises a package substrate which is electrically connected to the first integrated circuit die. The package substrate may be bonded to the electronic circuitry of the first integrated circuit die via at least one bump bond. The package substrate may be bonded to the electronic circuitry of the first integrated circuit die via a plurality of bump bonds, and each of said bump bonds may be located within a region located towards one end of the first integrated circuit die

In some embodiments the package substrate comprises a ground plane. The first package cover may comprise the package substrate.

In some embodiments the package substrate comprises a second integrated circuit die which at least partially overlies the first integrated circuit die. The first integrated circuit die may comprise analogue circuitry and the second integrated circuit die may comprise digital circuitry. The first integrated circuit die may be formed from a different manufacturing process node to the second integrated circuit die.

In some embodiments the package substrate may comprise the second integrated circuit die and a support layer, wherein the second integrated circuit die may be attached to the support layer and the support layer may form at least part of the outer surface of the package. The first integrated circuit die may be bump bonded to said support layer, and said second integrated circuit die may be electrically connected to the support layer. The first integrated circuit die may be bump bonded to the second integrated circuit die.

In some embodiments electrical contacts may be provided on a surface of the package substrate for electrically connecting to the first integrated circuit die. Vias may be provided through the package substrate connecting the electrical contacts to the electronic circuitry.

In some embodiments the MEMS transducer package comprises a filler layer of material disposed between the first package cover and at least part of the electronic circuitry of the first integrated circuit die.

In some embodiments the MEMS transducer is formed at a first surface of the first integrated circuit die. The first integrated circuit die may comprise a cavity wherein the MEMS transducer at least partly overlaps with the cavity. The cavity may extend through the first integrated circuit die from the MEMS transducer to an opening at a second surface of the first integrated circuit die.

In some embodiments the MEMS transducer package may further comprise a second package cover at the second surface of the first integrated circuit die to provide a volume defined by the cavity in the first integrated circuit die. The second package cover may comprise a sealing layer for sealing the cavity in the first integrated circuit die. The sealing layer may comprise a die attach film.

In some embodiments, together the first integrated circuit die, the first package cover and the second package cover form at least part of a side wall of the package.

The first integrated circuit dies may comprise at least one via electrically connected to the integrated electronic circuitry, the at least one via may run through the first integrated die to the second surface. The second package cover may comprise the package substrate and may be electrically connected to said at least one via of the first integrated circuit die at the second surface.

The area of the cavity at the MEMS transducer may smaller than at the second surface of the first integrated circuit die. The cavity may extend underneath the electronic circuitry.

In some embodiments at least part of the outer surface of the MEMS transducer package is formed by the integrated circuit die.

In some embodiments the first integrated circuit die comprises a shield structure for at least one of light shielding and EMI shielding. The shield structure may comprise a first area which comprises a plurality of metallic layers spaced in a first direction perpendicular to the surface of the first integrated circuit die. The metallic layers may be connected by conductive vias. The metallic layers and conductive vias may be connected to a ground contact on the surface of the first integrated circuit die. The ground contact may be connected to a ground contact of the first package cover.

The metallic layers and conductive vias may be connected to a ground plane within the first integrated circuit die that underlies at least part of the electronic circuitry.

In some embodiments the metallic layers and conductive vias are arranged such that substantially any path crossing through the shield structure in a direction perpendicular to the first direction passes through at least one of said metallic layers and/or one of said conductive vias.

In some embodiments the MEMS transducer package comprises multiple MEMS transducers on the first integrated circuit die. At least one of said multiple MEMS transducers may be a different type of transducer to at least one other of said multiple MEMS transducers.

The MEMS transducer may be a MEMS microphone.

An electronic device may comprises a MEMS transducer package as previously described.

The electronic apparatus may be: a portable device; a battery power device; a computing device; a communications device; a gaming device; a mobile telephone; a personal media player; a laptop, tablet or notebook computing device.

In another aspect of the present invention there is provided a MEMS transducer package comprising an integrated circuit die,
the first integrated circuit die comprising:
   an integrated MEMS transducer; and
   integrated electronic circuitry for operation of the MEMS transducer,

wherein
at least part of the outer surface of the MEMS transducer package is formed by the integrated circuit die.

In another aspect of the present invention there is provided a MEMS transducer package comprising an integrated circuit die; the integrated circuit die comprising:
an integrated MEMS transducer; and
integrated electronic circuitry for operation of the MEMS transducer, wherein in at least one plane the cross sectional area of the package is the same as the cross sectional area of the integrated circuit die.

In another aspect of the present invention there is provided a MEMS transducer package comprising:
a first semiconductor die; and
a second semiconductor die; wherein:
   the first semiconductor die comprises an integrated MEMS transducer and integrated analogue electronic circuitry for operation of the MEMS transducer;
   the second semiconductor die comprises digital circuitry, and
   the first and second semiconductor dies are electrically connected together such that the second semiconductor die at least partly overlaps the first semiconductor die.

In another aspect of the present invention there is provided a MEMS transducer apparatus comprising:
an integrated circuit die having a cavity therein;
a MEMS transducer formed on a first surface of the integrated circuit die, wherein said MEMS transducer at least partly overlaps with the cavity; and
a sealing layer attached to a second surface of the integrated circuit die so as to form a seal at the opening of the cavity in the second surface;
wherein the sealing layer comprises a die attach film attached to the second surface of the integrated circuit die.

In another aspect of the present invention there is provided a MEMS transducer apparatus comprising:
an integrated circuit die,
a MEMS transducer formed at a first location on a first surface of the integrated circuit die,
electronic circuitry formed at a second location on the first surface of the integrated circuit die for operation of the MEMS transducer, and
at least two bond terminals formed on the integrated circuit die for bump bonding the integrated circuit die to a further substrate, wherein
   the at least two bond terminals are formed within a region located towards one end the integrated circuit die such that the opposite end of the integrated circuit die is not constrained from expanding and/or contracting by any bump bonding.

In another aspect of the present invention there is provided an integrated circuit die comprising;
a semiconductor substrate,
an integrated MEMS transducer formed on the substrate,
integrated electronic circuitry formed on the substrate for providing operation of the MEMS transducer, and
a shield structure for providing at least one of EMI shielding and light shielding, wherein
   the shield structure is formed at least partly within the substrate.

The shield structure may comprise a first area which comprises a plurality of metal layers spaced in a first direction perpendicular to the surface of the integrated circuit die. The metallic layers may be connected by conductive vias.

The metallic layers and conductive vias may be connected to a ground contact on the surface of the first integrated circuit die. The metallic layers and conductive vias may be connected to a ground plane within the integrated circuit die that underlies at least part of the electronic circuitry.

The metallic layers and conductive vias may be arranged such that substantially any path crossing through the shield structure in a direction perpendicular to the first direction passes through at least one or said metallic layers and/or one of said vias.

For a better understanding of the present invention, and to show how it may be put into effect, reference will now be made, by way of example, to the accompanying drawings, in which:

FIGS. 1a and 1 b illustrate prior art MEMS transducer packages;

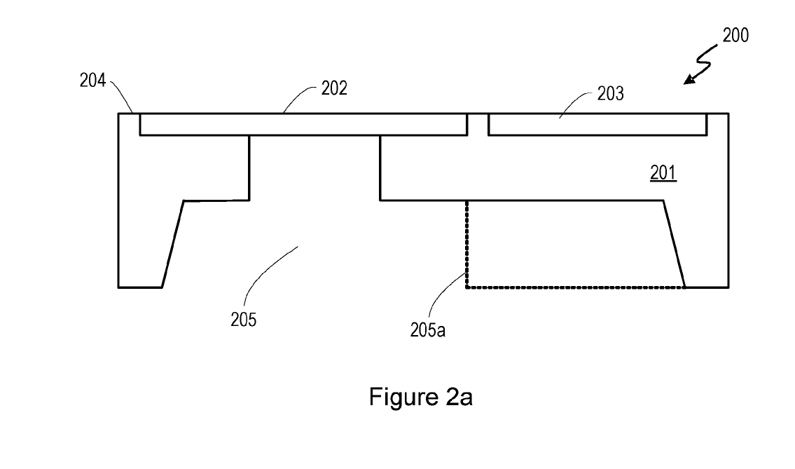

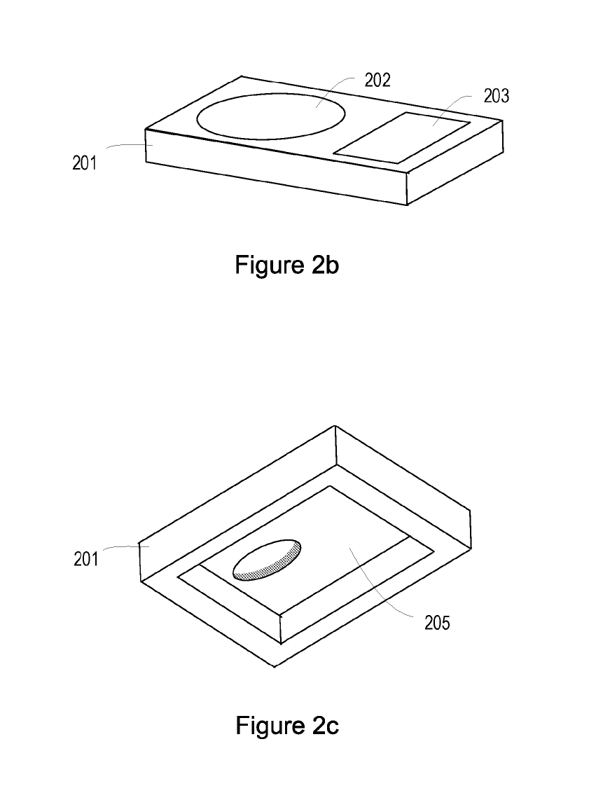

FIG. 2a illustrates a cross section of an integrated circuit die comprising a MEMS transducer;

FIG. 2b illustrates a three dimensional top view of the integrated circuit die shown in FIG. 2a;

FIG. 2c illustrates a three dimensional view of the underside of the integrated die;

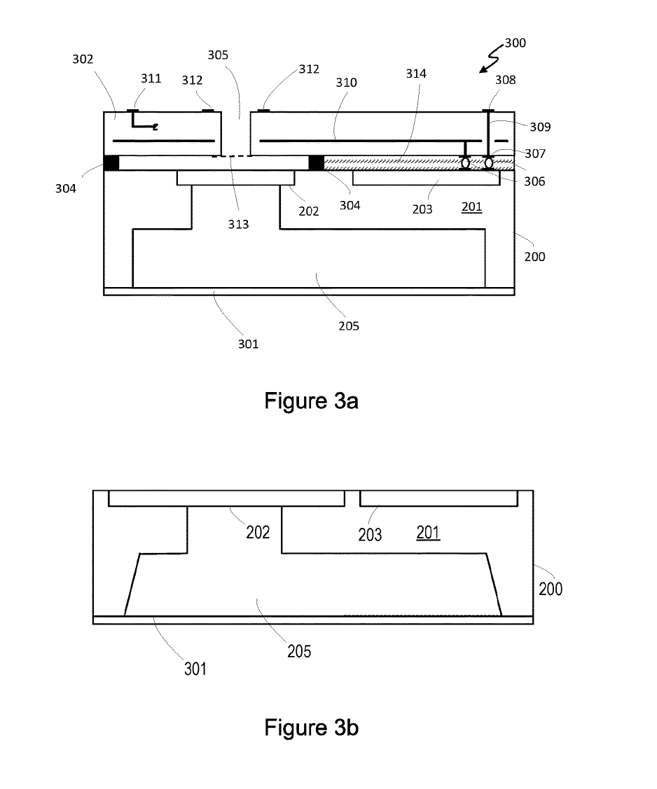

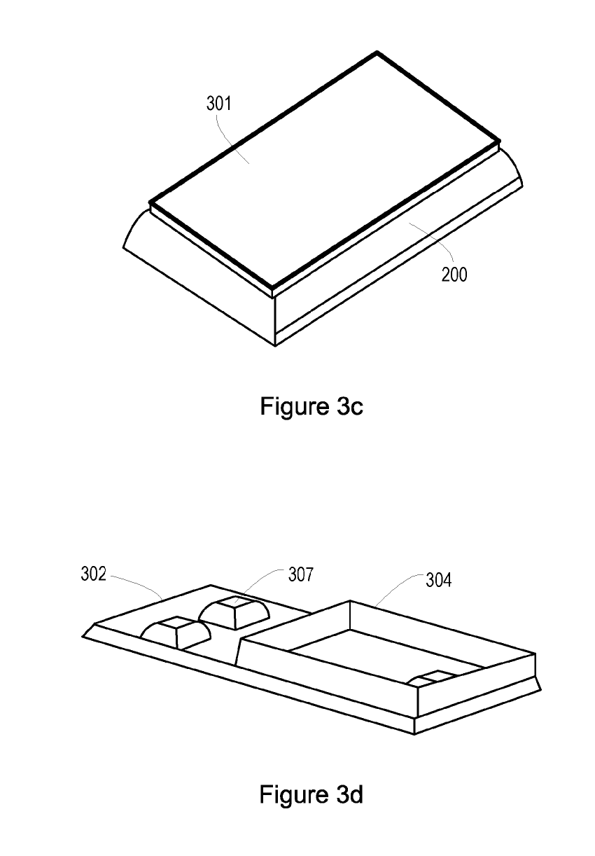

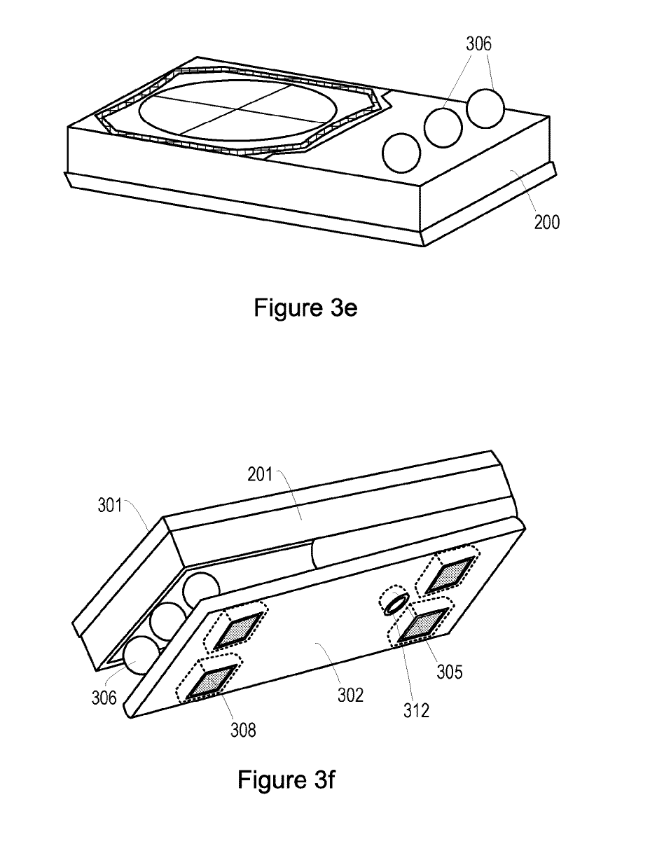

FIG. 3a illustrates a MEMS transducer package according to an embodiment of the present invention;

FIG. 3b illustrates a cross section of an integrated circuit die having a sealing layer;

FIG. 3c illustrates a three dimensional view of the underside of an integrated circuit die of FIG. 3b;

FIG. 3d illustrates a three dimensional view of a package substrate as may be used in the package of FIG. 3a;

FIG. 3e illustrates a three dimensional view of an integrated circuit die as may be used in the package of FIG. 3a;

FIG. 3f illustrates a three dimensional view of the MEMS transducer package of FIG. 3a.

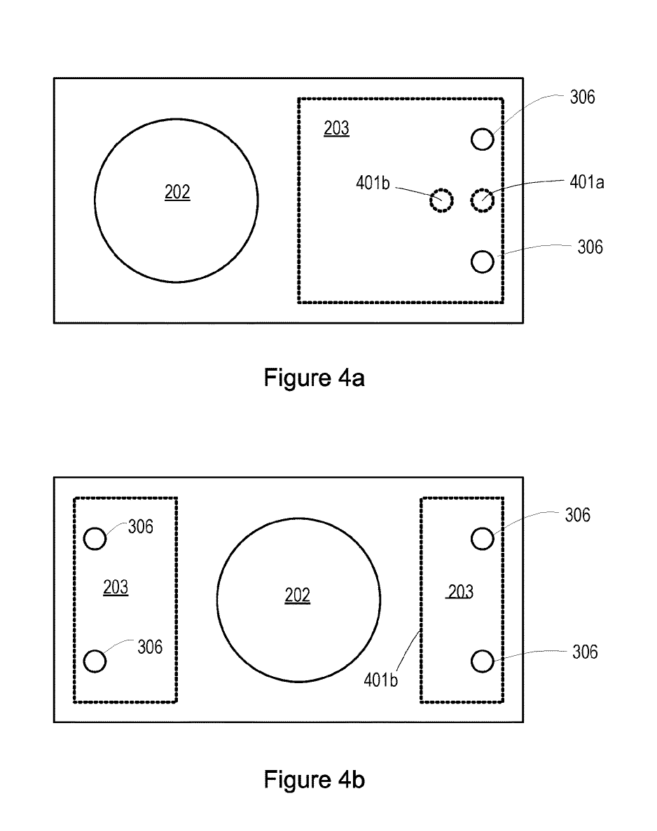

FIGS. 4a and 4b illustrate plan views of the example integrated circuit dies;

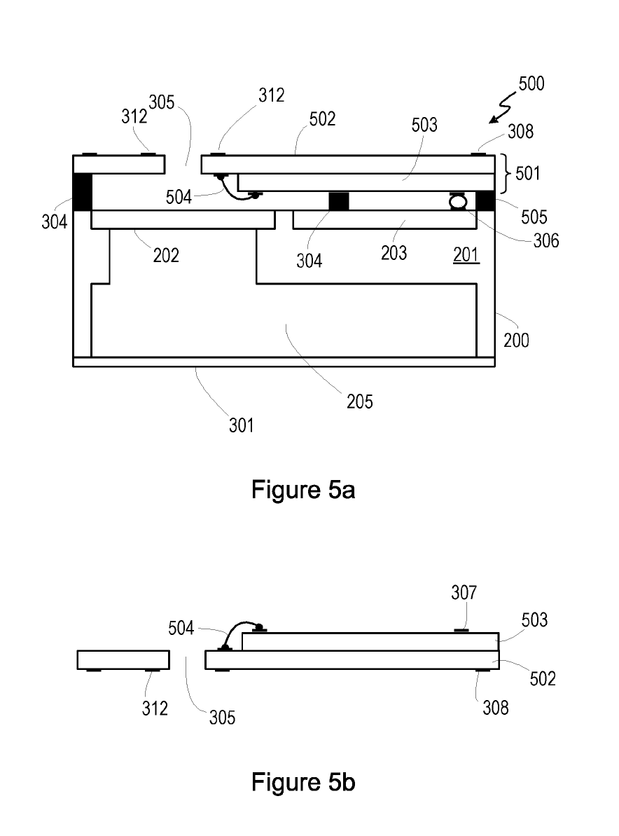

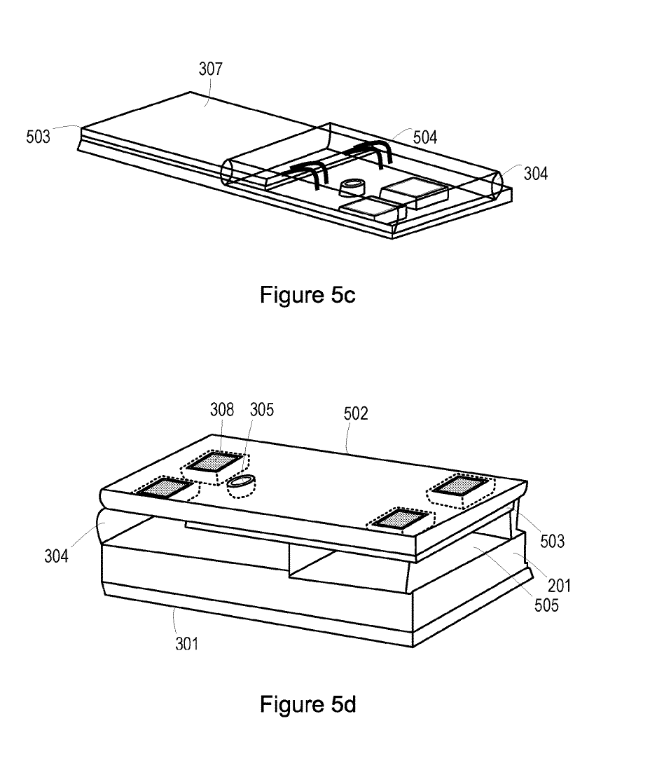

FIG. 5a illustrates a package substrate according to an embodiment of the invention;

FIG. 5b illustrates a cross sectional view of the package substrate of FIG. 5a;

FIG. 5c illustrates a three dimensional view of the package substrate shown in FIG. 5b with a barrier layer;

FIG. 5d illustrates a three dimensional view of the MEMS transducer package illustrated in FIG. 5a;

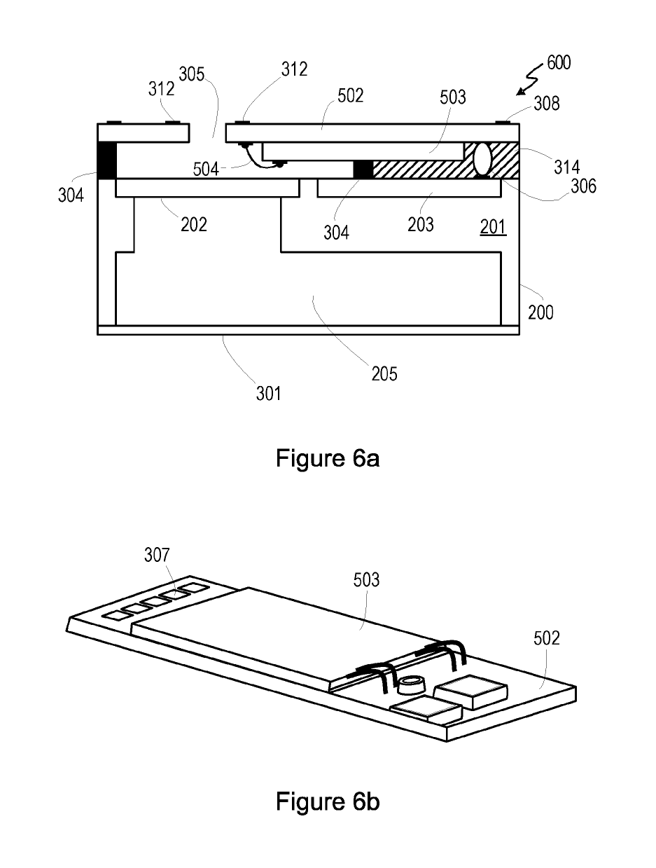

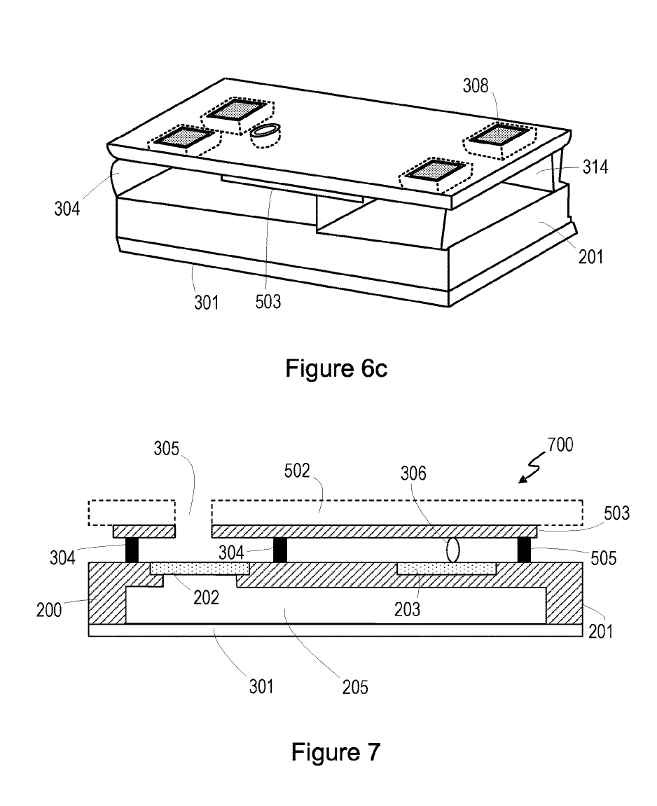

FIG. 6a illustrates a MEMS transducer package according to a further embodiment of the invention;

FIG. 6b illustrates a cross sectional view of the package substrate of FIG. 6a;

FIG. 6c illustrates a three dimensional view of the MEMS transducer package illustrated in FIG. 6a;

FIG. 7 illustrates MEMS transducer package according to a further embodiment of the invention;

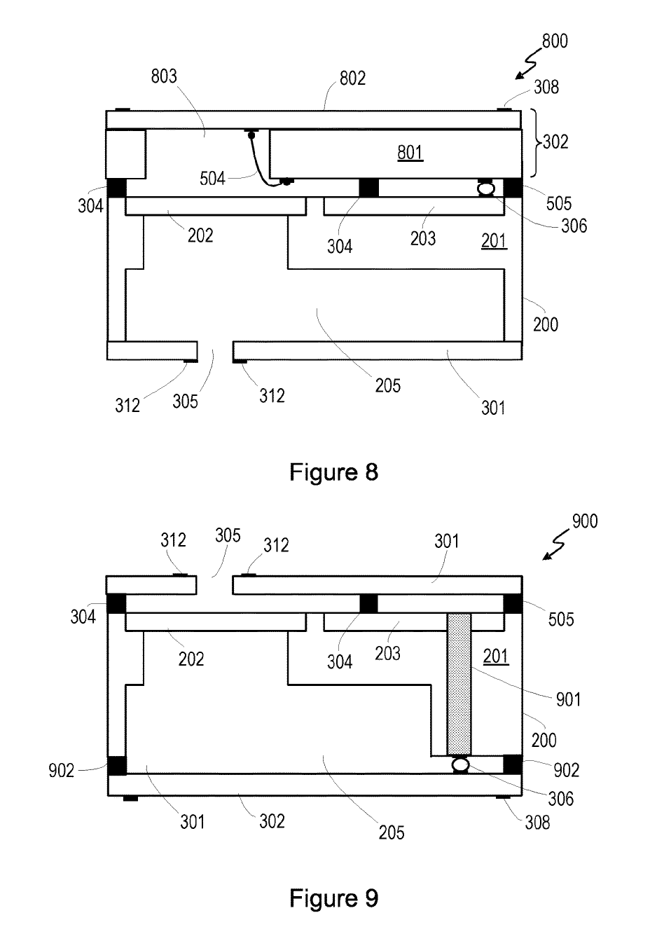

FIG. 8 illustrates a MEMS transducer package where sound is received via the die substrate cavity according to a further embodiment of the invention;

FIG. 9 illustrates a MEMS transducer package according to a further embodiment of the invention where a package substrate is electrically connected to the transducer die by vias in the transducer die;

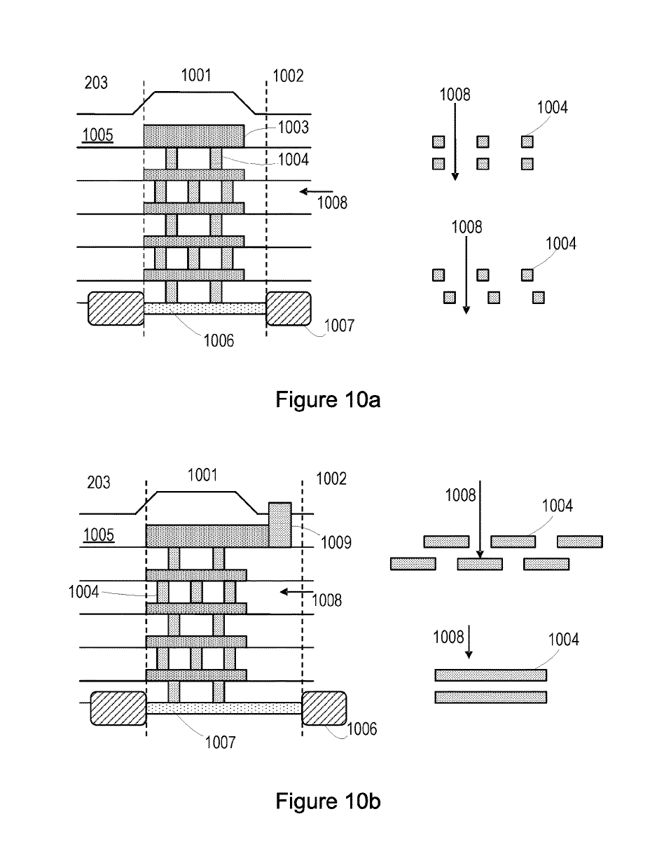

FIG. 10a illustrates a conventional seal-ring structure and FIG. 10b illustrates a seal-ring structure that may be formed in the integrated circuit die according to an embodiment of the invention; and

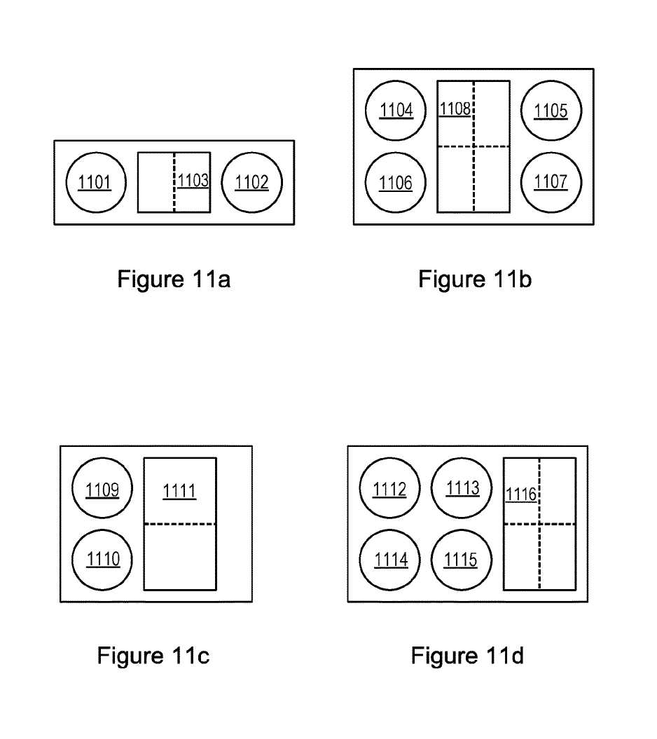

FIGS. 11a to 11d illustrates plan views of further example of integrated circuit dies according to embodiments of the invention.

### DESCRIPTION

Embodiments of the present invention provide improved MEMS transducer packages containing an integrated circuit die with an integrated MEMS transducer. The integrated circuit die may also comprise integrated electronic circuitry for operation of the MEMS transducer. In some embodiments the size of MEMS transducer package may be relatively small and/or reduced as compared to conventional packages and in some embodiments the footprint of the package may be substantially the same size as the footprint of the integrated circuit die comprising the MEMS transducer. In some embodiments at least part of the outer surface of the MEMS transducer package is formed by the integrated circuit die, for example part of a sidewall of the MEMS package. In some embodiments therefore the integrated circuit die comprises structures for providing shielding such as light shielding and/or EMI shielding. Additionally or alternatively some embodiments relate to MEMS transducer packages that may reduce the number of fabrication steps needed to form the package with respect to conventional methods. Embodiments also relate to MEMS transducer packages housing a plurality of integrated circuit dies.

Throughout this description any features which are similar to features in other figures have been given the same reference numerals.

In embodiments of the invention the MEMS transducer may be formed on an integrated circuit die together with at least some electronic circuitry. FIG. 2a illustrates a cross section of an integrated circuit die 200 comprising a MEMS transducer that may be used in an embodiment of the invention. FIGS. 2b and 2c show perspective views of the upper and lower surfaces respectively of the die 200. A die substrate 201, which may comprise a, semiconductor, e.g. silicon, substrate, comprises an integrated transducer 202 formed in a transducer region of the die and integrated electrical circuitry 203 formed in an electronics region of the die. The transducer 202 and electrical circuitry 203 may be formed by any suitable processing techniques, for instance by using CMOS compatible MEMS fabrication techniques. It will of course be appreciated that components of the MEMS transducer 202 and/or electronic circuitry 203 may extend beyond the plane of the upper surface 204 of the die substrate 201.

The transducer 202 may be a MEMS transducer such as a MEMS microphone. The electronic circuitry may, at least partly, comprise circuitry for operation of the MEMS transducer and may, for example, comprise a low noise amplifier or pre-amplifier circuit.

Note that as used in this specification the upper surface 204 of the transducer die 201 shall taken to mean the surface of the die on/in which the transducer 202 and electronic circuitry 203 is fabricated as illustrated in FIG. 2a. However it should be understood that the term upper should not be in any way construed as limiting to any particular orientation of the transducer die 201 during any fabrication step and/or it orientation in any package, or indeed the orientation of the package in any apparatus. The relative terms lower, above, below, underside, underneath etc. shall be construed accordingly.

A cavity 205 is formed in the die substrate 201 on the underside of the transducer 202. In other words the transducer is formed at a first, e.g. upper, surface of the integrated circuit die and the cavity may extend from through the integrated circuit die from the MEMS transducer to an opening at a second, e.g. lower, surface of the integrated circuit die. In embodiments of the present invention the cavity 205 may be configured so as to form at least part of a back volume in use, to allow the transducer membrane to move freely. As mentioned above transducers such as MEMS microphones may comprise a flexible membrane that can move in response to a pressure differential across the membrane. In use the membrane is typically disposed between first and second volumes, i.e. spaces or cavities that allow the membrane to deflect. Typically the first and second volumes fill with air in use but in some application the volumes could be filled with some other gas or liquid suitable for transmission of acoustic waves and/or responding to pressure differences. For a MEMS microphone a sound port, i.e. acoustic aperture, couples to the first volume to allow transmission of acoustic waves to one side of the membrane of the transducer. The first volume may be referred to as a front volume. The second volume on the other side of the membrane may be referred to as a back-volume.

It should be noted that the terms front and back-volume do not define any particular orientation of the transducer die. For example in some MEMS packages the back-volume may, at least partly be formed by the cavity in the die substrate but in other packages the cavity in the die substrate may be coupled to a sound port and may form at least part of a front volume.

It should also be noted that the terms front and back-volume do not denote any particular type of transducer construction. In particular for a MEMS capacitive transducer having a flexible membrane, the flexible membrane will typically support a first electrode relative to a second, substantially fixed, electrode. The second electrode may be supported by a support structure, which is separated from the flexible membrane by a transducer cavity or gap. The support structure supporting the second electrode is sometimes referred to as a back-plate and is typically designed to have a relatively low acoustic impedance at the frequencies of interest. In some designs of transducer the back-plate may be located above the membrane (when fabricated on the substrate) and thus the cavity 205 in the substrate extends beneath the membrane. In other designs however a back-plate may be located under the membrane and the cavity 205 in the die substrate may therefore extend through the die substrate to the membrane. Such a support structure, or back-plate, may therefore be located in the front volume or in the back volume.

The cavity 205 in the substrate die 201 may be formed in any known way. Advantageously the cavity may have a cross sectional area that increases towards the lower side of the die substrate 201. Thus the cavity immediately underlying the transducer 202 may have a first cross sectional area so that the area of the membrane is defined accurately. Towards the lower side of the die substrate 201 the cross sectional area of the cavity 205 may be larger so as to maximise the part of the back volume provided by the cavity 205. In some embodiments there may be a step change in the slope profile of the walls of the cavity 205. Such a cavity profile may be achieved by a multi-stage etching process such as described in the patent GB2451909. In the example shown in FIG. 2a the area of the cavity 205 towards the lower surface of the die substrate 201 extends such that part of the cavity underlies at least part of the electronics region of the die substrate 201. In some embodiments however the cavity may be configured such that it may not extend under the electrical circuitry 203, as illustrated by the dotted line 205a.

The electrical circuitry 203 may be connected to the transducer electrodes for operation of the transducer 202.

FIG. 3a illustrates a MEMS transducer package 300 according to an embodiment of the present invention. The package comprises an integrated circuit die 200 such as described above in respect to FIGS. 2a to 2c, and thus comprises a die substrate 201, having formed thereon an integrated transducer 202 and integrated electrical circuitry 203.

The integrated circuit die 200 is located between a first package cover which in this embodiment is provided by package substrate 302 and a second package cover which in this embodiment is provided by sealing layer 301.

In this embodiment the cavity 205 in the die substrate is sealed with a sealing layer 301 at the lower surface of the integrated circuit die. The sealing layer may be any suitable material such as PCB or a semiconductor layer or the like. FIGS. 3b and 3c illustrate respectively a cross-section of integrated circuit die 200 having a sealing layer 301 attached and a perspective view of the underside of such a die. In some embodiments however the sealing layer 301 may comprise die attach film (DAF). As one skilled in the art will be aware DAF is known which may be attached to a processed wafer before dicing. For example DAF may be used to attach the wafer to some dicing tape. The wafer may then be diced and heat applied to the dicing tape to cause it to expand and separate the individual dies. In embodiments of the present invention DAF may be used not only for the purposes of dicing but the DAF may form a functional part of the package itself. The use of DAF as a sealing layer for sealing the cavity 205 in the substrate die 201, i.e. as a second package cover, represents one novel aspect of embodiments of the present invention. In some embodiments the DAF which comprises the sealing layer 301 may be provided during the process of dicing the wafer and may be configured so that it can be retained on an individual die after a dicing step to provide the sealing layer. This can reduce the number of processing steps required to form the package 300. In some embodiments therefore the fabrication of a package according to an embodiment of the present invention may start with taking an integrated circuit die with a sealing layer such as illustrated in FIGS. 3b and 3c.

Whatever material is used for the second package cover, i.e. sealing layer 301, in the embodiment illustrated in FIG. 3a the cavity 205 in the substrate die provides a volume, for example a back-volume, for the transducer defined by the cavity 205. The sealing layer 301 thus encloses the back volume 205 and provides a stable acoustic environment for the electrode membrane of the transducer 202 to vibrate. The sealing layer 301 has an area which is sufficient to cover the opening of the cavity 205 in the lower surface of the substrate die 201. In some embodiments the footprint of the sealing layer 301 is not substantially greater than the footprint of the integrated circuit die 200—although in some embodiments, especially where the sealing layer is PCB or the like, the sealing layer may be arranged to extend beyond the edges of the integrated circuit die 200.

As mentioned other materials may be used to provide the sealing layer 301, whether in additional to or as an alternative to DAF. For example the sealing layer may comprise one or more of silicon and/or some other semiconductor, PCB, ceramic, laminate and/or plastic material.

Referring back to FIG. 3a the package 300 further comprises a package substrate 302. The package substrate 302 overlies the transducer 202 and a surface of the package substrate (the upper surface 303 as illustrated in FIG. 3a) forms an outer surface of the package 300. The package substrate thus forms the first package cover. The package substrate may be formed from any suitable material such as PCB or the like.

As used herein the term package substrate shall refer to a part of the package to which the integrated circuit die 200 is electrically connected for the transfer of signals and/or power for operation of the transducer. The package substrate will therefore itself typically have electrical connections for connecting the package, and thus the transducer and electronic circuitry, to external circuitry, for example to a PCB of a host device say.

The package substrate 302 thus forms part of the outer surface of the package, i.e. the first package cover. In embodiments of the present invention however the integrated circuit die 200 itself also forms part of the outer surface of the package, in particular part of a side wall of the package.

As can be seen in FIG. 3a, the sidewall of the package 300 is predominantly formed from the die substrate 201 which forms part of the integrated circuit die 200. Therefore, in this embodiment, the overall footprint of the microphone package 300 can be the same as the footprint of the integrated circuit die 200. In other words the footprint of the package substrate 302, i.e. the total area of the package in plan view, may be substantially the same as and/or substantially no greater than the footprint of the integrated circuit die 200. This results in a package having a relatively very small footprint which can be advantageous in many applications. A small package will require less space in a device. Packages according to embodiments of the present invention also avoid the cost associated with a separate sidewall structure such as required with conventional packages.

The package thus comprises the integrated circuit die 200 located between the package substrate 302 and the second package cover formed by the sealing layer 301. In embodiments of the invention the package substrate is not directly coupled to the second package cover as in the conventional approach but only via the die substrate 201.

It will be appreciated that in some embodiments the package substrate 302 and/or sealing layer 301 may extend beyond the edges of the integrated circuit die 200. However, even in these cases, a cross section of the package 300 will have an area of substantially the same size as the area of a cross section of the integrated die 200. In some embodiments the footprint of the package substrate 302 and/or sealing layer 301 may be greater than the footprint of the integrated circuit die 200 but the overall footprint of the package may still be relatively small, and smaller than would be achievable for a conventional package. For instance the footprint of the package may be no greater than 20% of the footprint of the integrated circuit die having the MEMS transducer. In some embodiments the footprint of the package may be no greater than 15% or no greater than 10% or no greater than 5% of the footprint of the integrated circuit die.

In the embodiment illustrated in FIG. 3a a first barrier 304 is provided between the package substrate 302 and the upper surface 204 of the integrated circuit die. The first barrier 304 surrounds the transducer 202 and defines, together with the package substrate 302, a volume on the upper side of the MEMS transducer which forms at least part of a front volume for the transducer and provides an environmental barrier. The package substrate thus may have an aperture 305 providing a sound port for the MEMS transducer, the aperture being located within the perimeter of the first barrier 304. It can be seen from FIG. 3a that the first barrier 304 may provide a barrier between the volume above the transducer region and the area above the electronic circuitry 203 and/or may provide itself part of the side wall of the package 300. The barrier 304 may conveniently comprise a layer of adhesive material which may, for instance be deposited, for instance using various printing techniques, in a desired location on the first integrated circuit die and/or the inside surface of the package substrate 302. FIG. 3d illustrates a perspective view of the inner surface of the package substrate 302 and illustrates that the first barrier 304 may be printed in a desired location on the package substrate 304 before bonding the package substrate to the integrated circuit die 200. Examples of suitable adhesive comprise, for example Epoxy, Silicone, Polyurethane, Acrylate, and/or Acrylic or compositions thereof.

The integrated circuit die is attached to the package substrate 302 and, as mentioned above, is electrically connected to the package substrate 302 to allow for operation of the transducer 202. In the embodiment illustrated in FIG. 3a the integrated circuit die 200 is bonded to the package substrate 302 by one or bump bonds 306, although any other suitable type of bond may be used. FIG. 3e illustrates that one or more balls of suitable material for bump bonding may be deposited on contact pads on the integrated circuit die 200. It will of course be appreciated that material may additionally or alternatively be provided on inner contacts 307 of the package substrate 302.

The bump bonds connect the electronic circuitry 203 of the integrated circuit die to inner electrical connections 307, e.g. bump bond pads, on the inside surface of the package substrate 302. The inner electrical connections may be electrically coupled to package electrical contacts 308 on the outer surface of the package 300, for instance by vias 309 through the package substrate. The package electrical contacts 309 allow for the package to be electrically connected in a host device for electrical connection with the electronic circuitry 203 and/or transducer 202 within the package 300.

In this embodiment, a ground plane 310 is provided within the package substrate 302. The ground plane, which may be a metallic or other conductive layer, may be configured to provide shielding against electromagnetic interference (EMI). The ground plane may be connected to a ground contact 311 for grounding in use. In some embodiments the ground plane 310 may itself be electrically connected to the integrated circuit die 200 through a bump bond 306 for connection with one or more EMI shielding layers within the integrated circuit die as will be described in more detail later.

In some embodiments a sealing ring 312 may be provided on the upper surface 303 of the package substrate 302 surrounding the aperture, e.g. sound port 305. For example if the package 300 is flip chip bonded onto a mother board or similar, a hole in the motherboard would be provided which would substantially line up with the aperture 305 in the package substrate 303. The sealing ring 312, which may be a metalized ring, i.e. a metalized annular bond pad, may be provided to aid in forming an acoustic channel in an assembled host device. For instance the package in use may be attached to a motherboard having an aperture for an acoustic channel. The provision of an acoustic sealing ring 312 can aid in forming an acoustic channel from within the package 300 to the other side of the motherboard.

Note that in some embodiments an environmental barrier 313 which is substantially acoustically transparent may be located across the aperture 305. This environmental barrier 313 may, for example, comprise a waterproof gauze or the like forming a waterproof membrane across the port to prevent moisture from entering into the first volume formed between the package substrate and the die substrate 201.

The waterproof gauze 313 may be screen-printed onto the package substrate, either on the inside surface—in which case it could be printed on an appropriate part of the inner surface of the package substrate. In one embodiment the waterproof membrane may be formed on or attached to the inner surface of the package substrate, for example by printing, to cover the aperture 305, as part of a printing process together with adhesive barrier 304. In other embodiments however the waterproof membrane may additionally or alternatively be formed on or attached to the outer surface of the package substrate, in which case the seal ring 312 may be provided on top of at least one environmental membrane layer. It would of course also be possible to use a multilayer package substrate where at least one environmental barrier layer is provided as an intermediate layer across the sound port aperture.

In some embodiments a second barrier layer is formed to protect and isolate the region of the electronic circuitry from the environment. In the embodiment illustrated in FIG. 3a a filler layer of material 314 is provided between the package substrate and at least part of the electronic circuitry of the integrated circuit die. This material could be back-filled into the gap between the package substrate and the integrated circuit die after bonding of the package substrate to the integrated circuit die. Alternatively a barrier layer similar to the barrier layer 304, and which could comprise the same and be deposited at the same material as the barrier layer 304, could be provided to surround the area of the electronic circuitry. In order to protect the electronic circuitry 203 from the presence of the barrier 304 or filler material 314 a passifying layer or the like could be located over at least some of the electrical circuitry. The filler material 314 may be the same or similar material to that forming the barrier layer 304 or any suitable material that can protect the underlying circuitry, for example the filler material may comprise at least one of Epoxy, Silicone, Polyurethane, Acrylate and/or Acrylic or compositions thereof.

FIG. 3f illustrates a three dimensional view of the MEMS transducer package 300 where the layer of filler material 314 has been omitted for clarity.

As mentioned above embodiments of the invention therefore provide packages for MEMS transducers, and especially to MEMS transducers on integrated circuit dies with integrated electronics, where the integrated circuit die forms part of the outer surface of the package. The package provides environmental protection as with conventional packages but the footprint of the package is much reduced compared to conventional packages. In addition the package may save on materials and the method of fabricating the package may require fewer steps than for conventional packages.

As mentioned therefore the size and shape of the package may be at least partly defined by the integrated circuit die, which may be itself at least partly dictated by the arrangement of the transducer and integrated electronic circuitry on the die. One skilled in the art will appreciated that there are many different ways in which electronic circuitry may be formed on a die together with a MEMS transducer, FIGS. 4a and 4b illustrate two examples and illustrate alternate plan views of the upper surface of the integrated circuit die illustrated in FIG. 2.

FIG. 4a illustrates an example of a die 200 where the transducer 202 is formed towards one side of the die and the electronic circuitry 203 is formed in a region towards an opposite side of the die, with electrical interconnects (not shown) connecting the electrodes of the transducer to appropriate parts of the circuitry. In other words the electronic circuitry 203 is substantially all located on one side of the transducer. Formed in the electronic circuitry region are pads or terminals for forming the bump bonds 306 with the package substrate. In the example illustrated in FIG. 4a all of the bump bonds 305 are formed towards one end of the die substrate 201. This can have advantages in terms of stress performance of the package. Referring back to FIG. 3a it can be seen that the die substrate 201 is attached to the package substrate by bump bonds 306 and by adhesive barrier layer 304 and possibly by filler material 314. The bump bonds 306 form relatively rigid bonds between the die substrate 201 and the package substrate 302, whereas the adhesive barrier layer 304 may have a degree of flexibility. In some embodiments the die substrate 201 may comprise different material(s) to the package substrate 302 and thus may have a different thermal coefficient of expansion. By locating the relatively inflexible bump bonds 306 at one end of the integrated circuit die this means that the other end is not constrained from expanding or contracting by bump bonding to the package substrate which may help reduce stress in the package in use. This means that the other end of the substrate 201 can expand and contract freely under different temperatures and pressures reducing any stress on the bump bonding 306

In some embodiments therefore all the bump bonds 306 may be formed within a region towards one end of the integrated circuit die 200. For example the bump bonds may all be located so that that each bump bond is located a distance from a first edge of the die which is no greater than 25% or 15% or 10% of the distance from the first edge to the opposite edge of the die substrate 201 (e.g. the width of the die). If the die is substantially rectangular in shape the first edge may be one of the short edges. In some embodiments, where there are at least three bump bonds, the bump bonds may be arranged to lie in a straight line so that any constraint on the expansion/contraction of the die substrate 201 applies in one direction only. However in some embodiments it may be preferred to arrange the bump bonds so that not all the bonds lie in a straight line. In FIG. 4a three bump bonds 306 are shown. As mentioned these may be located to lie in a straight line, i.e. when the middle bond, defined by an appropriate terminal/contact pad/solder ball etc. is in the position illustrated by 401a, or in any other desired configuration, for example when the middle is in the position illustrated 401b.

In some embodiments however it may be desirable to have bump bonds between the integrated circuit die and package substrate at two sides of the integrated circuit die to give the package a degree of structural stability. In some embodiments therefore there may be at least some bump bonding towards a first side of the integrated circuit die 200 and also some bump bonding towards a second opposite side. At least some of the bump bonding on one side could, in some embodiments, be purely for structural reasons and may not make an electrical connection. It would be possible to locate a bump bond remotely from the electronic circuitry region and connect the bond pad to the circuitry by suitable connections. However in some embodiments the electrical circuitry 203 could be located in more than one defined region on the integrated circuit substrate 201. FIG. 4b illustrates one example where there are two sections of electrical circuitry 203 on either side of the transducer 202. These sections of electrical circuitry 203 may be electrically connected together or may be separate. In this example there are bump bonds 306 located within both sections of electrical circuitry 203. In this embodiment the barrier layer 304 surrounding the transducer 202 would thus be located towards the centre of the package substrate. There may also be through vias on both ends of the package substrate for connecting to the bump bonding 306 on both sections of the electrical circuitry 203.

It will be appreciated that in the example illustrated in both FIGS. 4a and 4b a greater or fewer number of bump bonds 306 could be present. It will also be appreciated, as will be described later, that there may be more than one transducer formed on the integrated circuit die and/or that the shape of the integrated circuit die may also vary.

Whilst the embodiments described above are particularly relevant to packing an integrated circuit die comprising at least one MEMS transducer and integrated electronic circuitry, the same principles can be applied to packaging of dies comprising just one or more MEMS transducers without any associated electronic circuitry.

Embodiments of the present invention also relate to packages that include a first integrated circuit die on which is formed a MEMS transducer in a package with a second integrated circuit die. The second integrated circuit die may comprise additional circuitry.

FIG. 5a illustrates a package 500 according to an embodiment of the invention. The first integrated circuit die 200 is bonded to a package substrate 501 forming a first package cover in a similar fashion to the embodiments described above. In this embodiment however the package substrate 501 comprises a support layer 502 and a second integrated circuit die 503.

FIG. 5b illustrates a cross section of the package substrate 501. The second integrated circuit die 503 may comprise electronic circuitry for operation of the transducer on the first integrated circuit die 200 and may work with or complement the electronic circuitry on the first integrated circuit die 200. For example if the MEMS transducer 202 is a MEMS microphone the electronic circuitry 203 integrated on the first integrated circuit die 200 may comprise some analogue electronics for read-out of the MEMS microphone, e.g. low noise amplifier or pre-amplifier or the like. As one skilled in the art will appreciate the signals from MEMS sense transducers such as microphones are typically very small signals and it can be advantageous to integrate an amplifier with the transducer to avoid unwanted capacitances due to bond pads and the like which can adversely affect the signal to noise ratio. The second integrated circuit die may comprise electronic circuitry for processing the amplified signal from the first integrated circuit die and may for instance comprise at least some digital electronic circuitry. By providing two integrated circuit dies in the package the circuitry on each die can be optimised for a given purpose. For example the circuitry on the first integrated circuit die may be formed using a different manufacturing process node to the second integrated circuit die, i.e. a different type of semiconductor processing with a different minimum feature size. For example a 65 nm, or lower, process may be suitable for forming digital circuitry but may not be suited or cost effective for the required analogue circuitry. In embodiments of the present invention the analogue circuitry on the first integrated circuit die can be formed using a suitable process for analogue circuitry and the digital circuitry on the second integrated circuit die can be formed using a suitable process for digital circuitry. Typically the digital circuitry will have a lower process node, i.e. gate length (W/L), than the analogue circuitry. It will of course be appreciated that the first integrated circuit die may additionally comprise some digital circuitry and the on the second integrated circuit die may additionally or alternative comprise analogue circuitry. In some embodiments the second integrated die may be an ultra thin integrated circuit die. Ultrathin semiconductor processing is a known technology.

The second integrated circuit die is attached to a support layer 502 of the package substrate 501 within the package. An outer surface of the support layer 501 thus forms the top surface of the package on which the terminal pads 308 and acoustic sealing ring 312 are disposed. Inner contact 307 for bump bonding may then be provided on the surface of the second integrated die 503. The second integrated die 503 may be wire-bonded 504 to the support layer 502 of package substrate. Vias in the support layer may connect the circuitry of the second integrated circuit die to outer package contacts 308. The support layer may be any suitable material such as PCB, a plastic material, a semiconductor layer etc.

As described above a barrier layer 304, e.g. of a suitable adhesive, may be provided to surround the transducer. In this embodiment, the barrier 304 may be provided with the wire-bonding 504 contained within its perimeter. It may therefore be formed at least partially on the second integrated circuit die 503. The digital electronics of the second integrated circuit die 503 may therefore be protected by a passivation layer. Again the barrier layer may be deposited, e.g. by printing techniques, on the package substrate prior to bonding the package substrate to the first integrated circuit die 200. FIG. 5c illustrates a perspective view of the package substrate with deposited barrier layer. Additionally or alternatively the barrier 304 could be deposited on the first integrated circuit die. It would also be possible for the whole of the second integrated circuit die, and the wire bonding, to fall outside of the cavity defined by the barrier 304.

Additionally other connection techniques, such as using vias through the second integrated circuit die 503 could be used to connect to the support layer 502.

Again there may be a layer of filler material disposed between the package substrate and the first integrated circuit die outside of the barrier 304, which in the embodiment would be located between the first and second integrated circuit dies 200 and 503. Alternatively, as shown in FIG. 5a a second barrier layer 505 is provided around the peripherally of the package, i.e. the periphery of the first integrated circuit die and/or package substrate outside the transducer barrier layer 304.

It will be appreciated that in this embodiment the second integrated circuit die 503 of the package substrate 501 at least partly overlies the first integrated circuit die. In some embodiments the whole of the second integrated circuit die may overlie the first integrated circuit die such that the footprint of the package may again be defined by the footprint of the first integrated circuit die. In this embodiment where the sound port is formed in the package substrate 501 the second integrated circuit die may be smaller than the first integrated circuit die so that the sound port is formed in the support layer 502. In the embodiment illustrated in FIG. 5a part of the second integrated circuit die also forms part of the outer surface of the package, forming part of the sidewalls of the package on one side of the package. FIG. 5d illustrates a perspective view of the package of FIG. 5a.

A ground pane similar to that shown in FIG. 3a may be provided in the package substrate support layer 502.

FIG. 6a illustrates an alternative MEMS transducer package 600 according to an embodiment of the invention. The embodiment of FIG. 6a is similar to that described with reference to FIG. 5a and again the package substrate (which forms the first package cover) comprises a support layer 502 and a second integrated circuit die 503. In the embodiment of FIG. 6a however the first integrated circuit die substrate 201 is bump bonded to the support layer 502. The second integrated circuit die may be electrically connected to the support layer via wire-bonding 504 or any suitable electrical connection. FIG. 6b illustrates a perspective view of the package substrate in this embodiment. It will be appreciated that in this embodiment there is an area of support layer 502 which is not covered by the second integrated circuit die 503 which, in use, overlies part of the electronic circuitry 203 on the first integrated circuit die 200.

As with FIG. 3a, it will be appreciated that the package substrate 501 and/or cover 301 could extend beyond the edges of the integrated circuit die 200.

FIG. 7 illustrates MEMS transducer package 700 according to a further embodiment of the invention.

In this embodiment a second integrated circuit die 503 is provided, which overlies the whole of the transducer region of the first integrated circuit die. Hence, the aperture 305 which forms the sound port is formed in the second integrated circuit die 503.

In this embodiment, if the second integrated circuit die 503 has sufficient structural integrity, the second integrated circuit die may provide the package substrate without the need for an additional supporting layer 502. In such an embodiment the top outer surface of the package may be provided by a surface of the second integrated circuit die 503 and it is the second integrated circuit die that forms the package substrate and acts as the first package cover. The barrier 304 around the transducer 202 is thus located between the first and second integrated circuit dies 200 and 503.

The second integrated circuit die may also extend over the electrical circuitry 203 on the first integrated circuit die and be bump bonded thereto be bump bonds 306. Vias through the second integrated circuit die may provide connections to outer electrical connections of the package (not shown in FIG. 7). The second integrated circuit die may comprise a conducting layer to act as a ground plane.

In other embodiments, particularly if the second integrated circuit die 503 is ultra thin and unable to provide the required support on its own, a support layer 502 may also be provided which can support at least a portion of the second integrated circuit die 503 as described above. In this case the aperture 305 will pass through both the support layer 502 and the second integrated circuit die 503.

In embodiments having a support layer the second integrated circuit may not extend over all of the first integrated circuit die and the bump bonding may be directly to the support layer 502 as discussed above in relation to FIG. 6a.

In the embodiments described above the integrated circuit die 200 is effectively flip-chip bonded to the package substrate 302/501. Generally this means that the volume formed on one side of the transducer between the surface of the die substrate 201 and the package substrate is not very large. In the embodiments described above therefore this volume is formed as part of the front volume and the sound port is formed in the package substrate. This volume between the package substrate and the integrated circuit die is thus in acoustic communication with a volume outside of the package so that acceptable acoustic performance can be achieved. The volume on the other side of the transducer, i.e. formed at least partly by the cavity 205 in the die substrate 201, is typically a larger volume due to the fact that the cavity extends, from the transducer, all the way through the die substrate 201 and, as mentioned, may have a cross sectional area that increases through the die substrate 201. Thus the cavity 205 may be of sufficient size to act as a satisfactory back-volume. Such embodiments, where the sound port is formed in the package substrate, may sometimes be referred to as being a bottom port arrangement. Typically the package substrate is used to connect to further components, such as a PCB of a host device.

It would however be possible to use a first package cover that comprises a package substrate with at least one spacer layer such that the volume between the package substrate 302/501 and the integrated circuit die 200 in the region of the transducer is large enough to function as a satisfactory back-volume, as illustrated in FIG. 8.

FIG. 8 shows a package 800 wherein the integrated circuit die 200 is bonded to a package substrate 302 that includes a relatively thick spacer layer 801 in the vicinity of the electronic circuitry 203 but which does not extend over the transducer 202, and a further outer layer 802 which extends across the whole area of the package. The spacer layer 801 may comprise an integrated circuit die such as described above with reference to FIGS. 5 and 6 and/or may comprise one or more layer of materials such as PCB or the like. This may result in extending the overall height of the package compared to the embodiments without such a spacer layer but it will be noted that the spacer layer is connected to the integrated circuit die 200 and the footprint of the package can still be defined by the footprint of the integrated circuit die 200.

The integrated circuit die 200 may be bump bonded to the spacer layer of the package substrate, which may be electrically connected to the outer layer 802 for connecting to the electrical connections 308 for the package.

The package substrate may be substantially sealed, i.e. there is no aperture in the package substrate layer 802. The cavity 803 between the package substrate 302 and the integrated circuit die 200 may thus be substantially sealed from the outside of the package. The sound port may then be formed by aperture 305 being formed in the sealing layer 301. This provides a top-port embodiment with flip-chip bonding of the integrated circuit die 200 to the package substrate 302. In this embodiment the sealing layer 301 may comprise a material such as PCB, ceramic or a semiconductor later or the like and may be provided with seal ring 312.

In some embodiments the cavity 205 in the die substrate 201 may be arranged as back volume in use, but the cavity 205 may be sealed by the package substrate as illustrated in FIG. 9. In other words the package substrate may be used as the second package cover. FIG. 9 shows a package 900 where the sealing layer 301 is provided as the first package cover on the upper side of the integrated circuit die 200. The sealing layer, which may for instance comprise PCB or the like, may be attached to the upper surface of the integrated circuit die substrate 201 by adhesive barrier layers 304 and 505 as described previously. An aperture 305 in the sealing layer 301 provides the sound port. Thus the volume formed between the upper surface of the integrated circuit die 200 and the sealing layer may be relatively small as this cavity is acoustically coupled to a volume outside of the package.

The package substrate in this embodiment is connected to the lower side of the integrated circuit die 200 to form the second package cover. The package substrate thus seals cavity 205 to provide a back-volume in use. To provide an electrical connection between the circuitry 203 of the integrated circuit die and the package substrate 302 vias 901 may be formed through the integrated circuit die substrate 201. Such vias, which may be through-silicon vias (TSVs), could, for instance, be formed when performing the deep etch to form cavity 205. The vias may terminate at the lower end with ball-drops and/or eutectic pads or the like suitable for connection to the package substrate. The package substrate may therefore be bump-bonded or similar to the underside of the integrated circuit die 200 and an adhesive layer 902, which may e similar to layer 304, may be used to adhere the package substrate to the integrated circuit die 200 and seal the cavity 205. This allows for a top port embodiment without the need for a spacer layer on the upper side of the integrated circuit die.

Again it should be noted that the term upper surface is used in relation to the integrated circuit die 200 with regard to the surface of the die on/in which the transducer 202 and electronic circuitry 203 are fabricated and no particular orientation of the transducer die 201 during any fabrication step and/or it orientation in any package, or indeed the orientation of the package in any apparatus in implied by this term. The term lower surface thus refers to the opposite surface of the die substrate 201.

In the embodiments described above the sealing layer 301 may be a substantially planar layer. It will be appreciated however that the sealing layer could form part of a cover having a recess formed therein to expand the size of the front or back volume in use. For example the sealing layer 301 could comprise a spacer layer around the periphery of the sealing layer, in a similar manner as described above with reference to the package substrate of FIG. 8.

As mentioned previously in embodiments of the present invention part of the outer surface of the package may be formed by the integrated circuit die 200. In conventional packages the integrated circuit die is housed in an enclosure formed by a separate structure and the housing can be designed to protect the integrated circuit not only from moisture, dust and other possible environmental contaminants but also from unwanted interference. In particular the conventional housing can shield the integrated circuit die from electromagnetic interference and/or can shield the sensitive electronic circuitry from light. As will be understood by one skilled in the art the electronic circuitry should ideally be substantially shielded top prevent photons from reaching the circuitry and potentially resulting in errors in operation.

In some embodiments the packages described above may therefore be provided with one or more conformal coating layers on the outside of the package to provide light and/or EMI shielding. For example a metallic layer on or within a base layer such as a polymer layer may be coated on the outside of the packages discussed above. A relatively thin coating layer may be used such that the footprint of the package may still be substantially defined by the footprint of the integrated circuit die.

In some embodiments however at least one shield structure may be formed within the integrated circuit die 200 itself. In some embodiments the shield structure may comprise at least part of seal ring structure, such as a CMOS seal ring.

It is known in the fabrication of integrated circuits, such as in CMOS processing, to form a structure known as a seal ring around the circuit components. The seal ring structure is formed during fabrication of the electronic circuitry and typically comprises a series of overlapping regions of metallisation connected by vias. FIG. 10a illustrates a conventional seal ring structure. The left hand side of FIG. 10a illustrates that a seal ring structure 1001 may be formed in a region between the electronic circuitry 203 and a peripheral region 1002 of the die, where scribe lines for dicing may be formed in the wafer before dicing. The seal ring structure comprises various layers of metal 1003 connected by vias 1004 in the inter-metal dielectric 1005. The lower part of the seal ring structure may be connected to a p well 1006 with the areas outside of the seal ring being field oxide 1007.

The seal ring structure is typically provided to surround the region of active circuitry and is located between the active circuitry and scribe lanes used for dicing wafers into individual dies. The seal ring structure serves to keep the various layer of the integrated circuit together and helps prevent delamination of the various inter-metal dielectric layers during a dicing process.

In embodiments of the present invention a seal-ring like structure is provided to provide light and/or EMI shielding for the integrated circuit die in a package according to embodiments of the present invention. Such a structure could be in addition to a conventional seal-ring structure but in some embodiments the seal-rind structure may be configured to provide shielding in addition to preventing delamination during dicing.

In embodiments of the invention therefore a shield structure may be formed using conventional processing steps, thus avoiding the need for any substantial additional process steps.

The conventional seal ring structure shown in FIG. 10a is not grounded and provides limited, if any, EMI shielding. Also the seal string structure does not act to block light from passing through the dielectric material into the sensitive electronic areas. The right hand side of FIG. 10a illustrates in plan view two typical arrangements of the vias 1004 viewed from the direction indicated by arrow 1008, i.e. a direction which is perpendicular to the normal to the surface of the integrated circuit die.

In embodiments of the invention the seal ring structure is modified from the conventional arrangement to provide EMI shielding and/or light shielding. FIG. 10b illustrates a portion of integrated circuit die 200 having a shield structure based on a seal-ring according to an embodiment of the invention. The shield structure is formed in a first region 1001 which may be arranged to at least partly surround the sensitive areas, such as the region of electronic circuitry 203. The shield structure comprises, in a first direction perpendicular to the upper surface of integrated circuit die, a plurality of metallic layers 1003 connected by conductive vias 1004. In embodiments of the present invention the metallic layers and vias may be arranged so as to provide substantial light shielding, e.g. to block a substantial portion of any light from passing to the sensitive circuit areas. The metallic layers and vias may be arranged such that substantially any path crossing through the shield structure in a direction perpendicular to the first direction passes through at least one or said metallic layers and/or one of said vias. Thus the vias may be arranged such that the majority of paths through the shield structure in a side-on direction, i.e. perpendicular to the (global) normal to the surface of the die, will encounter at least metallic layer or via. In other words the straight line paths for light to get into the sensitive areas are substantially blocked.

For example the vias may be formed as extended vias with a relative offset between vias such that, when viewed from the direction 1008, a continuous area of metal/vias is perceived. Additionally or alternatively at least some of the via may be arranged as continuous walls.

Additionally or alternatively a contact 1009 may be provided to allow for the seal ring to be electrically connected to a ground plane or ground contact. As illustrated in FIG. 10b the contact may be at the upper surface of the die substrate 201 but in some embodiments there may additionally or alternatively by a ground contact at the lower side of the die substrate 201. Typically the seal ring structure is formed only in the CMOs layers of the die substrate and does not extend all the way through the die substrate but a through-silicon via could be provided to connect to a ground terminal.

The ground contact 1009 may, in use, be connected to a metal layer that overlies the circuitry region 203 to provide an upper EMI shield. Additionally or alternatively the ground contact could be connected to a ground plane in the package substrate (or cover layer depending on the embodiment). The lower part of the seal ring structure may be connected to a ground plane within the silicon substrate, e.g. a well region 1007. A ground plane could extend through the die substrate under the circuitry region.

In this way the CMOS seal ring structure may be used to provide mechanical strength to the circuitry to help prevent delamination as is known in the art but may also provide EMI shielding and/or light shielding. Thus the CMOS seal ring may have a dual functionality in shielding from EMI and light, or in other words, a combined shielding effect for protection against electromagnetic radiation from a plurality of different bandwidths in the electromagnetic spectrum.

As discussed previously the integrated circuit die comprising the MEMS transducer may comprise more than one MEMS transducer. FIGS. 11-11d illustrate example of various integrated circuit dies that could be packaged in embodiment of the present invention.

FIG. 11a illustrates a plan view of one example of an integrated circuit die 200. In this embodiment two transducers 1101 and 1102 are provided with electrical circuitry 1103 disposed between them. This electrical circuitry 1103 may be either shared or separate electrical circuitry. The electrical circuitry may be analogue or digital.

FIG. 11b illustrates a plan view of another example of an integrated circuit die 200. In this embodiment four transducers 1104, 1105, 1106 and 1107 are provided with electrical circuitry 1108. Again this electrical circuitry may be individual circuitry for each transducer, or a shared electrical circuitry. The electrical circuitry may be analogue or digital.

FIG. 11c illustrates a plan view of a further example of an integrated circuit die 200. In this embodiment two transducers 1109 and 1110 are provided with electrical circuitry 1111 to one side of the die substrate 201. This embodiment could be easily combined with the embodiment described with respect to FIG. 4a wherein any bump bonding is contained within a certain proportion of one end of the die substrate 201. Again, the electrical circuitry 1111 may be individual electrical circuitry for each transducer, or shared electrical circuitry.

FIG. 11d illustrates a plan view of the integrated circuit die 200. In this embodiment 4 transducers 1112-1115 are provided with electrical circuitry 1116 to one side of the substrate 201. In this embodiment the four transducers are different types of transducers, for example an absolute pressure sensor, a microphone, an ultrasonic sensor and an accelerometer, although it will be appreciated that other types of transducers or any other combination of transducers could be used.

It will be appreciated that any of the embodiments with multiple transducers, including those not directly illustrated, could be implemented with any of the embodiments describing the full MEMS package that have been illustrated thus far, albeit with certain modifications such as providing separate barriers for each transducer.

Embodiments of the present invention are particularly applicable to packing for MEMS sensor transducers, especially capacitive transducers such as MEMS microphones. It will also be appreciated that other types of MEMS capacitive sensors could be implemented, for example accelerometers, pressure sensors, proximity sensors or flow meters.

Embodiments may be implemented in a host device, especially a portable and/or battery powered host device such as a mobile telephone, and audio player, a video player, a PDA, a mobile computing platform such as a laptop computer or tablet and/or a games device for example or in an accessory device, such a headset, earbud (possibly noise-cancelling), or microphone assembly, designed for wired, or wireless connection with such host devices, possibly via multi-wire cables, multi-pole jacks, or optical fibres and connectors.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A MEMS transducer package comprising a first integrated circuit die, the first integrated circuit die comprising:
an integrated MEMS transducer; and
integrated electronic circuitry for operation of the MEMS transducer;
wherein the footprint of the MEMS transducer package is substantially the same size as the footprint of the integrated circuit die.

2. A MEMS transducer package as claimed in claim 1 further comprising a first package cover which overlies the MEMS transducer, wherein at least part of the outer surface of the MEMS transducer package is formed by the first package cover.

3. A MEMS transducer package as claimed in claim 2 wherein a barrier is provided around the MEMS transducer between the first package cover and the first integrated circuit die.

4. A MEMS transducer package as claimed in claim 3 wherein there is a first volume defined by the first integrated circuit die, the barrier and the first package cover.

5. A MEMS transducer package as claimed in claim 3 wherein the barrier comprises a layer of an adhesive material.

6. A MEMS transducer package as claimed in claim 2 wherein the first package cover comprises an aperture.

7. A MEMS transducer package as claimed in claim 6 further comprising a sealing ring on the outer surface of the first package cover surrounding the aperture.

8. A MEMS transducer package as claimed in claim 6 further comprising a water-resistant membrane disposed across said aperture.

9. A MEMS transducer package as claimed in claim 1 comprising a package substrate which is electrically connected to the first integrated circuit die.

10. A MEMS transducer package as claimed in claim 9 wherein the package substrate is bonded to the electronic circuitry of the first integrated circuit die via at least one bump bond.

11. A MEMS transducer package as claimed in claim 10 wherein the package substrate is bonded to the electronic circuitry of the first integrated circuit die via a plurality of bump bonds, and each of said bump bonds is located within a region located towards one end of the first integrated circuit die.

12.-21. (canceled)

22. A MEMS transducer package as claimed in claim 2 comprising a filler layer of material disposed between the first package cover and at least part of the electronic circuitry of the first integrated circuit die.

23. A MEMS transducer package as claimed in any preceding claim 1 wherein:
the MEMS transducer is formed at a first surface of the first integrated circuit die;
the first integrated circuit die comprises a cavity wherein said MEMS transducer at least partly overlaps with the cavity; and
the cavity extends through the first integrated circuit die from the MEMS transducer to an opening at a second surface of the first integrated circuit die.

24. A MEMS transducer package as claimed in claim 23 further comprising a second package cover at the second surface of the first integrated circuit die to provide a volume defined by the cavity in the first integrated circuit die.

25. A MEMS transducer package as claimed in claim 24 wherein the second package cover comprises a sealing layer for sealing the cavity in the first integrated circuit die.

26. (canceled)

27. A MEMS transducer package as claimed in claim 24, when dependent directly or indirectly on claim 2, wherein together the first integrated circuit die, the first package cover and the second package cover form at least part of a side wall of the package.

28. A MEMS transducer package as claimed in claim 24 wherein:
the first integrated circuit dies comprises at least one via electrically connected to the integrated electronic circuitry, the at least one via running through the first integrated die to the second surface; and
wherein the second package cover comprises the package substrate and is electrically connected to said at least one via of the first integrated circuit die at the second surface.

29. A MEMS transducer package as claimed in claim 23 wherein the area of the cavity at the MEMS transducer is smaller than at the second surface of the first integrated circuit die.

30. A MEMS transducer package as claimed in claim 23 wherein the cavity extends underneath the electronic circuitry.

31. A MEMS transducer package as claimed in claim 1 wherein at least part of the outer surface of the MEMS transducer package is formed by the integrated circuit die.

32-39. (canceled)

40. A MEMS transducer package as claimed in claim 1 wherein said MEMS transducer is a MEMS microphone.

41. An electronic device comprising a MEMS transducer package as claimed in claim 1.

42. An electronic apparatus as claimed in claim 41 wherein said apparatus is at least one of: a portable device; a battery power device; a computing device; a communications device; a gaming device; a mobile telephone; a personal media player; a laptop, tablet or notebook computing device.

43. A MEMS transducer package comprising an integrated circuit die,
the first integrated circuit die comprising:
an integrated MEMS transducer; and
integrated electronic circuitry for operation of the MEMS transducer,
wherein
at least part of the outer surface of the MEMS transducer package is formed by the integrated circuit die.

44. A MEMS transducer package comprising an integrated circuit die; the integrated circuit die comprising:
an integrated MEMS transducer; and
integrated electronic circuitry for operation of the MEMS transducer, wherein in at least one plane the cross sectional area of the package is the same as the cross sectional area of the integrated circuit die.

45.-52. (canceled)
